(19) United States
(12) Patent Application Publication
(10) Pub. No.: US 2016/0181469 A1
(43) Pub. Date: Jun. 23, 2016

(54) SEMICONDUCTOR LIGHT-EMITTING DEVICE AND MANUFACTURING METHOD THEREOF

(71) Applicant: PlayNitride Inc., Tainan City (TW)

(72) Inventors: Shen-Jie Wang, Tainan City (TW); Yu-Chu Li, Tainan City (TW); Ching-Liang Lin, Tainan City (TW)

(21) Appl. No.: 14/941,681

(22) Filed: Nov. 16, 2015

(30) Foreign Application Priority Data
Dec. 23, 2014 (TW) 103144975

(51) Int. Cl. H01L 33/00; H01L 33/32; H01L 33/12

(52) U.S. Cl. CPC H01L 33/0025; H01L 33/12; H01L 33/0075; H01L 33/325

(57) ABSTRACT

A semiconductor light-emitting device including a first N-type semiconductor layer, a P-type semiconductor layer, and a light-emitting layer is provided. The first N-type semiconductor layer contains aluminum, and the concentration of the N-type dopant thereof is greater than or equal to 5×10¹⁸ atoms/cm³. The light-emitting layer is disposed between the first N-type semiconductor layer and the P-type semiconductor layer. A manufacturing method of a semiconductor light-emitting device is also provided.

### CROSS-REFERENCE TO RELATED APPLICATION

This application claims the priority benefit of Taiwan application serial no. 103144975, filed on Dec. 23, 2014. The entirety of the above-mentioned patent application is hereby incorporated by reference herein and made a part of this specification.

### BACKGROUND

1. Field of the Invention

The invention is directed to a light-emitting device and more particularly, to a semiconductor light-emitting device.

2. Description of Related Art

With the evolution of photoelectrical technology, traditional incandescent bulbs and fluorescent lamps have been gradually replaced by solid-state light sources of the new generation, such as light-emitting diodes (LEDs). The LEDs have advantages, such as long lifespans, small sizes, high shock resistance, high light efficiency and low power consumption and thus, have been widely adopted as light sources in applications including household lighting appliances as well as various types of equipment. Beside being widely adopted in light sources of backlight modules of liquid crystal displays (LCDs) and household lighting appliances, the application of the LEDs have been expanded to street lighting, large outdoor billboards, traffic lights and the related fields in recent years. As a result, the LEDs have been developed as the light sources featuring economic power consumption and environmental protection.

An LED is basically formed by an N-type semiconductor layer, a light-emitting layer and a P-type semiconductor layer. A travelling path of electrons in the N-type semiconductor layer tend to be centralized in the path with least resistance, which easily leads to an area in a light-emitting layer for electrons and holes recombining together to be small and centralized, such that light emitted from the LED is too centralized with no uniformity. In this way, it may also cause light-emitting efficiency of the LED to be reduced. This is called as a current crowding effect, and the current crowding effect easily leads to a transient rise in local current density, and as a result, wall-plug efficiency will be reduced, or a junction temperature will be increased.

Moreover, most developers of solid-state light sources recently make effort to pursue good luminance efficiency. Subjects with respect to improving the luminance efficiency of the LEDs are generally divided into how to improve internal quantum efficiency (i.e., luminance efficiency of a light-emitting layer) and how to improve external quantum efficiency (which is further affected by light extraction efficiency). However, in a conventional gallium nitride (GaN) LED, band gaps of a P-type GaN semiconductor layer and an N-type GaN semiconductor layer are approximate to a band gap of the light-emitting layer, such that blue light or ultraviolet (UV) light emitted from the light-emitting layer is easily absorbed thereby, which leads to reduced luminance efficiency of the LED.

### SUMMARY

The invention provides a semiconductor light-emitting device having better light-emitting efficiency and more uniform light-emitting characteristics.

The invention provides a manufacturing method of a semiconductor light-emitting device capable of manufacturing a semiconductor light-emitting device having better light-emitting efficiency and more uniform light-emitting characteristics.

According to an embodiment of the invention, a semiconductor light-emitting device including a first N-type semiconductor layer, a P-type semiconductor layer and a light-emitting layer is provided. The first N-type semiconductor layer contains aluminum, and the concentration of the N-type dopant of the first N-type semiconductor layer is greater than or equal to 5×10¹⁸ atoms/cm³. The light-emitting layer is disposed between the first N-type semiconductor layer and the P-type semiconductor layer, and light emitted from the light-emitting layer includes blue light, ultraviolet (UV) light or a combination thereof.

According to an embodiment of the invention, a semiconductor light-emitting device including a first N-type semiconductor layer, a P-type semiconductor layer and a light-emitting layer is provided. The first N-type semiconductor layer contains aluminum, and a resistivity of the first N-type semiconductor layer is anisotropic. The light-emitting layer is disposed between the first N-type semiconductor layer and the P-type semiconductor layer.

According to an embodiment of the invention, a manufacturing method of a semiconductor light-emitting device is provided. The method includes: providing a substrate; alternately forming a plurality of N-type GaN layers and a plurality of unintentionally doped AlGaN layers on the substrate to form a first N-type semiconductor layer; forming a light-emitting layer on the first N-type semiconductor layer; and forming a P-type semiconductor layer on the light-emitting layer.

In an embodiment of the invention, the first N-type semiconductor layer is an N-type aluminum gallium nitride (AlGaN) layer.

In an embodiment of the invention, the N-type dopant is silicon.

In an embodiment of the invention, the first N-type semiconductor layer includes a plurality of N-type gallium nitride (GaN) layers and a plurality of unintentionally doped AlGaN layers which are alternately stacked.

In an embodiment of the invention, a resistivity of the first N-type semiconductor layer is anisotropic.

In an embodiment of the invention, the resistivity of the first N-type semiconductor layer in a thickness direction thereof is greater than the resistivity of the first N-type semiconductor layer in a direction perpendicular to the thickness direction.

In an embodiment of the invention, the semiconductor light-emitting device further includes a substrate, an unintentionally doped semiconductor layer and a dislocation termination layer. The unintentionally doped semiconductor layer is disposed on the substrate and located between the first N-type semiconductor layer and the substrate. The unintentionally doped semiconductor layer contains aluminum. The dislocation termination layer is disposed between the first N-type semiconductor layer and the unintentionally doped semiconductor layer. The unintentionally doped semiconductor layer includes a plurality of GaN layers and a plurality of AlGaN layers which are alternately stacked.

In an embodiment of the invention, the semiconductor light-emitting device further includes a buffer layer disposed between the unintentionally doped semiconductor layer and the substrate.

In an embodiment of the invention, the semiconductor light-emitting device further includes a substrate and a second N-type semiconductor layer. The second N-type semiconductor layer is disposed on the substrate and located between the first N-type semiconductor layer and the substrate. The second N-type semiconductor layer contains aluminum.

In an embodiment of the invention, the semiconductor light-emitting device further includes a dislocation termination layer disposed between the first N-type semiconductor layer and the second N-type semiconductor layer.

In an embodiment of the invention, the semiconductor light-emitting device further includes a buffer layer disposed between the second N-type semiconductor layer and the substrate.

In an embodiment of the invention, the concentration of aluminum in the second N-type semiconductor layer is greater than the concentration of aluminum in the first N-type semiconductor layer.

In an embodiment of the invention, the second N-type semiconductor layer includes a plurality of N-type GaN layers and a plurality of unintentionally doped AlGaN layers which are alternately stacked.

In an embodiment of the invention, the resistivity of the second N-type semiconductor layer is anisotropic.

In an embodiment of the invention, the manufacturing method of the semiconductor light-emitting device further includes: before forming the first N-type semiconductor layer, alternately forming a plurality of GaN layers and a plurality of AlGaN layers on the substrate to form an unintentionally doped semiconductor layer, wherein the first N-type semiconductor layer is formed on the unintentionally doped semiconductor layer.

In an embodiment of the invention, the manufacturing method of the semiconductor light-emitting device further includes: before forming the first N-type semiconductor layer, alternately forming a plurality of N-type GaN layers and a plurality of unintentionally doped AlGaN layers on the substrate to form a second N-type semiconductor layer, wherein the first N-type semiconductor layer is formed on the second N-type semiconductor layer, and the concentration of aluminum in the second N-type semiconductor layer is greater than the concentration of aluminum in the first N-type semiconductor layer.

In the semiconductor light-emitting device provided by the embodiments of the invention, since the first N-type semiconductor layer contains aluminum, a band gap of the first N-type semiconductor layer can be increased and have greater difference from a band gap of the light-emitting layer. Thereby, the proportion of the first N-type semiconductor layer absorbing the light emitted from the light-emitting layer can be reduced, so as to enhance light-emitting efficiency of the semiconductor light-emitting device. Moreover, in the semiconductor light-emitting device provided by the embodiments of the invention, since the resistivity of the first N-type semiconductor layer is anisotropic, electrons can have a greater drift range in the first N-type semiconductor layer to suppress a current crowding effect, so as to enhance light-emitting efficiency and light-emitting uniformity of the semiconductor light-emitting device. In the manufacturing method of the semiconductor light-emitting device provided by the embodiments of the invention, the plurality of N-type GaN layers and the plurality of unintentionally doped AlGaN layers are alternately formed on the substrate to form the first N-type semiconductor layer, and thus, electrons tends to laterally diffuse easily in the first N-type semiconductor layer. In this way, the current crowding effect can be effectively suppressed, so as to enhance the light-emitting efficiency and the light-emitting uniformity of the semiconductor light-emitting device.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional diagram illustrating a semiconductor light-emitting device according to an embodiment of the invention.

FIG. 2 is a cross-sectional diagram illustrating a semiconductor light-emitting device according to another embodiment of the invention.

FIG. 3 is a cross-sectional diagram illustrating a semiconductor light-emitting device according to yet another embodiment of the invention.

FIG. 4 is a cross-sectional diagram illustrating a semiconductor light-emitting device according to still another embodiment of the invention.

FIG. 5 is a cross-sectional diagram illustrating a semiconductor light-emitting device according to yet another embodiment of the invention.

FIG. 6 is a cross-sectional diagram illustrating a semiconductor light-emitting device according to still another embodiment of the invention.

FIG. 7A and FIG. 7B are cross-sectional diagrams illustrating a process of manufacturing method of a semiconductor light-emitting device according to an embodiment of the invention.

### DESCRIPTION OF EMBODIMENTS

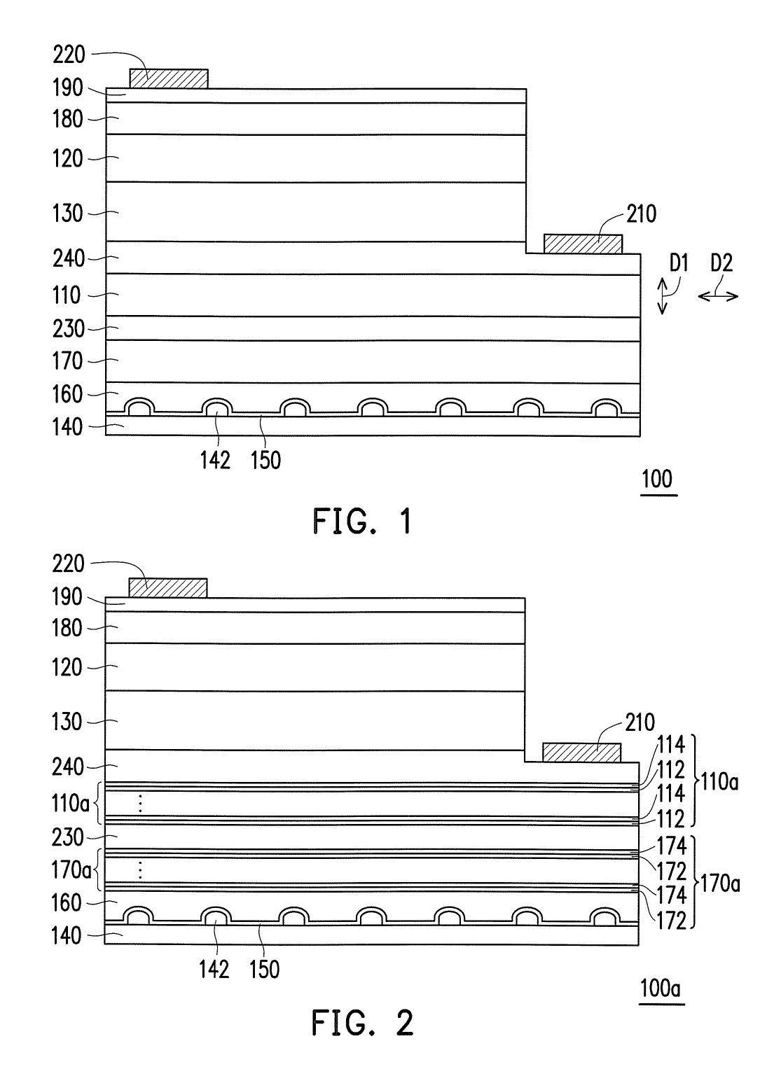

FIG. 1 is a cross-sectional diagram illustrating a semiconductor light-emitting device according to an embodiment of the invention. With reference to FIG. 1, a semiconductor light-emitting device 100 in this embodiment includes a first N-type semiconductor layer 110, a P-type semiconductor layer 120 and a light-emitting layer 130. The light-emitting layer 130 is disposed between the first N-type semiconductor layer 110 and the P-type semiconductor layer 120. In the present embodiment, light emitted from the light-emitting layer 130 includes blue light, such that the semiconductor light-emitting device 100 is a blue light-emitting LED, for example. However, in other embodiments, the light emitted from the light-emitting layer 130 may include blue light, ultraviolet (UV) light or a combination thereof. In the present embodiment, the light-emitting layer 130 is, for example, a multiple quantum well (MQW) layer formed by alternately stacking a plurality of indium gallium nitride (InGaN) layers and a plurality of GaN layers, which is capable of emitting the blue light. Additionally, in the present embodiment, the first N-type semiconductor layer 110 contains aluminum, and the concentration of the N-type dopant of the first N-type semiconductor layer 110 is greater than or equal to 5×10¹⁸ atoms/cm³.

In the present embodiment, the first N-type semiconductor layer 110 is an N-type aluminum gallium nitride (AlGaN) layer. Additionally, in the present embodiment, the N-type dopant of the first N-type semiconductor layer 110 is silicon. Namely, in the present embodiment, the first N-type semiconductor layer 110 is a silicon-doped AlGaN layer.

In the semiconductor light-emitting device 100 of the present embodiment, since the first N-type semiconductor layer 110 contains aluminum, a band gap of the first N-type semiconductor layer 110 can be increased and have greater difference from a band gap of the light-emitting layer 130. Thereby, a proportion of the first N-type semiconductor layer 110 absorbing the light emitted from the light-emitting layer 130 can be reduced, so as to enhance light-emitting efficiency of the semiconductor light-emitting device 100.

In the present embodiment, the resistivity of the first N-type semiconductor layer 110 is anisotropic. In the semiconductor light-emitting device 100 of the present embodiment, since the resistivity of the first N-type semiconductor layer 110 is anisotropic, electrons can have a greater drift range in the first N-type semiconductor layer to suppress a current crowding effect, so as to enhance light-emitting efficiency and light-emitting uniformity of the semiconductor light-emitting device 110. For example, in the present embodiment, the resistivity of the first N-type semiconductor layer 110 in a thickness direction D1 thereof is greater than the resistivity of the first N-type semiconductor layer 110 in a direction D2 (i.e., a lateral direction) perpendicular to the thickness direction D1. The electrons tend to travel in a path with less resistance and thus, tend to diffuse in a direction D2 (i.e., the lateral direction) with a less resistivity, such that the electrons have a more dispersed distribution path before entering the light-emitting layer 130. In this way, the electrons have a larger drift rang in the first N-type semiconductor layer 110 to suppress the current crowding effect, so as to enhance the light-emitting efficiency and the light-emitting uniformity of the semiconductor light-emitting device 110. In other words, the first N-type semiconductor layer 110 may serve as an electron spreading layer.

In the present embodiment, the P-type semiconductor layer 120 is, for example, a P-type GaN layer or a P-type aluminum indium gallium nitride (AlInGaN) layer. Additionally, in the present embodiment, the semiconductor light-emitting device 100 further includes a contact layer 180 disposed on the P-type semiconductor layer 120, and the P-type semiconductor layer 120 is disposed between the contact layer 180 and the light-emitting layer 130. In the present embodiment, the P-type dopant of the P-type semiconductor layer 120 is a group IIA element dopant, e.g., a magnesium (Mg) dopant.

In the present embodiment, the semiconductor light-emitting device 100 may further include an N-type semiconductor layer 240 disposed between the first N-type semiconductor layer 110 and the light-emitting layer 130. The N-type semiconductor layer 240 is, for example, an N-type gallium nitride (GaN) layer or an N-type AlInGaN layer. The N-type semiconductor layer 240 may serve as a strain relief layer. However, in other embodiments, the semiconductor light-emitting device 100 may not include the N-type semiconductor layer 240, and the first N-type semiconductor layer 110 directly contacts the light-emitting layer 130.

Additionally, in the present embodiment, the semiconductor light-emitting device 100 further includes a first electrode 210 and a second electrode 220. The first electrode 210 is electrically connected to the N-type semiconductor layer 240, e.g., disposed on the N-type semiconductor layer 240, and the second electrode 220 is disposed on the contact layer 180. In other embodiments, the first electrode 210 may also be electrically connected to the first N-type semiconductor layer 110, e.g., disposed on the first N-type semiconductor layer 110.

In the present embodiment, the semiconductor light-emitting device 100 further includes a transparent conductive layer 190 (e.g., an indium tin oxide (ITO) layer) disposed on the contact layer 180, and the second electrode 220 is disposed on the transparent conductive layer 190. The contact layer 180 is configured to reduce contact resistance between the transparent conductive layer 190 and the P-type semiconductor layer 120. In the present embodiment, the contact layer 180 is an ohmic contact layer which is a P-type doped layer with a high concentration P-type dopant or an N-type doped layer with a high concentration N-type dopant. In an embodiment, the concentration of an electron donor or an electron acceptor in the contact layer 180 is greater than or equal to 10²⁰ atoms/cm³, and thus, the conductivity of the contact layer 180 is similar to the conductivity of a conductor. For example, the contact layer 180 may be a P-type InGaN layer, e.g., an Mg-doped InGaN layer. Additionally, in an embodiment, the contact layer may be, for example, an oxygen-contained P-type InGaN layer.

In the present embodiment, the semiconductor light-emitting device 100 further include a substrate 140, a nucleation layer 150, a buffer layer 160 and an unintentionally doped semiconductor layer 170. In the present embodiment, the substrate 140 is a patterned sapphire substrate having surface patterns 142 (e.g., protruding patterns) to provide a light-scattering effect, so as to improve light extraction efficiency. The nucleation layer 150, the buffer layer 160 and the unintentionally doped semiconductor layer 170 are stacked in sequence on the substrate 140. In the present embodiment, the nucleation layer 150 and the buffer layer 160 are made of, for example, unintentionally doped GaN, aluminum nitride (AlN) or aluminum gallium nitride (AlGaN). In the embodiments of the invention, “unintentionally doped” refers to not intentionally causing a semiconductor material to be a P-type doped semiconductor or an N-type doped semiconductor in the process.

In the present embodiment, a method of forming the first N-type semiconductor layer 110 having the anisotropic resistivity is alternately forming a plurality of N-type GaN layers and a plurality of unintentionally doped AlGaN layers on the substrate 140. The alternately stacked N-type GaN layers and unintentionally doped AlGaN layers are grown in a high-temperature condition, and thus, when the first N-type semiconductor layer 110 is formed, the alternately formed N-type GaN layers and unintentionally doped AlGaN layers are blended together to form a one-layer N-type AlGaN layer. However, the one-layer N-type AlGaN layer fowled in this manner can have the anisotropic resistivity.

Moreover, in the present embodiment, the unintentionally doped semiconductor layer 170 is located between the first N-type semiconductor layer 110 and the substrate 140 and contains aluminum. In the present embodiment, a method of forming the unintentionally doped semiconductor layer 170 may be alternately forming a plurality of GaN layers and a plurality of AlGaN layers on the substrate 140. The alternately formed GaN layers and AlGaN layers are grown in a high-temperature condition, and thus, when the unintentionally doped semiconductor layer 170 is formed, the alternately formed GaN layers and AlGaN layers are blended together to form a one-layer AlGaN layer. However, in other embodiments, the unintentionally doped semiconductor layer 170 may also be an unintentionally doped GaN layer. Additionally, in other embodiments, the unintentionally doped semiconductor layer 170 may be replaced by a second N-type semiconductor layer which contains aluminum. Additionally, the concentration of aluminum in the second N-type semiconductor layer is greater than the concentration of aluminum in the first N-type semiconductor layer 110. In an embodiment, the concentration of aluminum in the second N-type semiconductor layer falls within a range from 0.5 to 40, and the concentration of aluminum in the first N-type semiconductor layer 110 falls within a range from 0.5 to 25.

In the present embodiment, a method of forming the second N-type semiconductor layer may be alternately forming a plurality of N-type GaN layers and a plurality of unintentionally doped AlGaN layers on the substrate 140. The alternately formed N-type GaN layers and unintentionally doped AlGaN layers are grown in a high-temperature condition, and thus, when the second N-type semiconductor layer is formed, the alternately formed N-type GaN layers and unintentionally doped AlGaN layers are blended to form a one-layer N-type AlGaN layer. The second N-type semiconductor layer formed in this manner can have an anisotropic resistivity.

In the present embodiment, the semiconductor light-emitting device 100 further includes a dislocation termination layer 230 disposed between the first N-type semiconductor layer 110 and the unintentionally doped semiconductor layer 170, and the buffer layer 160 is disposed between the unintentionally doped semiconductor layer 170 and the substrate 140. The dislocation termination layer 230 is, for example, an AlN layer or an AlGaN layer, serving to terminate the dislocation accumulated during the process of growing the layers (e.g., the buffer layer 160 and the unintentionally doped semiconductor layer 170) thereunder, such that layers above the dislocation termination layer 230 can have better epitaxial quality. If the unintentionally doped semiconductor layer 170 is replaced by the second N-type semiconductor layer, the dislocation termination layer 230 may be located between the first N-type semiconductor layer 110 and the second N-type semiconductor layer. Alternatively, the dislocation termination layer 230 may be located between the second N-type semiconductor layer and the buffer layer 160. Or, in other embodiments, the semiconductor light-emitting device 100 may not include the dislocation termination layer 230.

FIG. 2 is a cross-sectional diagram illustrating a semiconductor light-emitting device according to another embodiment of the invention. With reference to FIG. 2, a semiconductor light-emitting device 100a of the present embodiment is similar to the semiconductor light-emitting device 100 of the embodiment illustrated in FIG. 1, but different therefrom in below. In the semiconductor light-emitting device 100a of the present embodiment, a first N-type semiconductor layer 110a includes a plurality of N-type GaN layers 112 and a plurality of unintentionally doped AlGaN layers 114 which are alternately stacked. A method of forming the first N-type semiconductor layer 110a of the present embodiment is similar to the method of forming the first N-type semiconductor layer 110 of FIG. 1, both of which are implemented by alternately forming a plurality of N-type GaN layers 112 and a plurality of unintentionally doped AlGaN layers 114, though the first N-type semiconductor layer 110a may be identified as having the plurality of N-type GaN layers 112 and the plurality of unintentionally doped AlGaN layers 114 which are alternately stacked by using a precision instrument (e.g., a composition analyzer), instead of the blended one-layer N-type AlGaN layer.

Furthermore, in the present embodiment, an unintentionally doped semiconductor layer 170a includes a plurality of GaN layers 172 and a plurality of AlGaN layers 174 which are alternately stacked. A method of forming the unintentionally doped semiconductor layer 170a is similar to the method of forming the unintentionally doped semiconductor layer 170 illustrated in FIG. 1, both of which are implemented by alternately forming a plurality of GaN layers 172 and a plurality of AlGaN layers 174, though the unintentionally doped semiconductor layer 170a may be identified as having the plurality of GaN layers 172 and the plurality of AlGaN layers 174 which are alternately stacked by using a precision instrument (e.g., a composition analyzer), instead of the blended one-layer AlGaN layer. In another embodiment, the unintentionally doped semiconductor layer 170a may also include alternately stacked N-type GaN layers and unintentionally doped AlGaN layers, which may be identified by using the precision instrument.

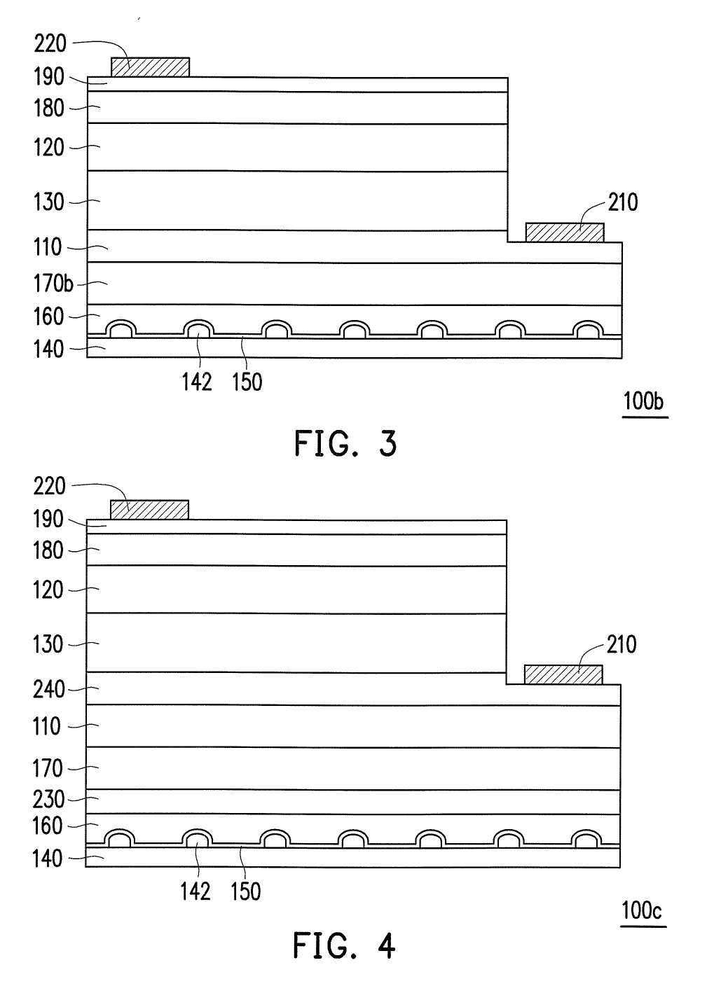

FIG. 3 is a cross-sectional diagram illustrating a semiconductor light-emitting device according to yet another embodiment of the invention. A semiconductor light-emitting device 100b of the present embodiment is similar to the semiconductor light-emitting device 100 of the embodiment illustrated in FIG. 1, but different therefrom in below. In the semiconductor light-emitting device 100b of the present embodiment, there is no N-type semiconductor layer 240 between the light-emitting layer 130 and the first N-type semiconductor layer 110, and the first N-type semiconductor layer 110 directly contacts the light-emitting layer, and the first electrode 210 is disposed on the first N-type semiconductor layer 110. Additionally, the semiconductor light-emitting device 100b includes the second N-type semiconductor layer 170b configured to replace the unintentionally doped semiconductor layer 170. In the present embodiment, the dislocation termination layer 230 depicted in FIG. 1 may not exist between the first N-type semiconductor layer 110 and the second N-type semiconductor layer 170b, and the second N-type semiconductor layer 170b directly contacts the buffer layer 160. In another embodiment, the semiconductor light-emitting device 100b may not include the buffer layer 160, and the second N-type semiconductor layer 170b directly contacts the nucleation layer 150. Alternatively, in other embodiments, the semiconductor light-emitting device 100b may not include the second N-type semiconductor layer 170b, and the first N-type semiconductor layer 110 directly contacts the buffer layer 160 or directly contacts the nucleation layer 150 (in case the semiconductor light-emitting device 100b does not have the buffer layer 160).

FIG. 4 is a cross-sectional diagram illustrating a semiconductor light-emitting device according to still another embodiment of the invention. A semiconductor light-emitting device 100c of the present embodiment is similar to the semiconductor light-emitting device 100 of the embodiment illustrated in FIG. 1, but different therefrom in below. In the semiconductor light-emitting device 100c of the present embodiment, the dislocation termination layer 230 is disposed between the unintentionally doped semiconductor layer 170 and the buffer layer 160, and the unintentionally doped semiconductor layer 170 directly contacts the first N-type semiconductor layer 110. However, in other embodiments, the unintentionally doped semiconductor layer 170 may also be replaced by the second N-type semiconductor layer.

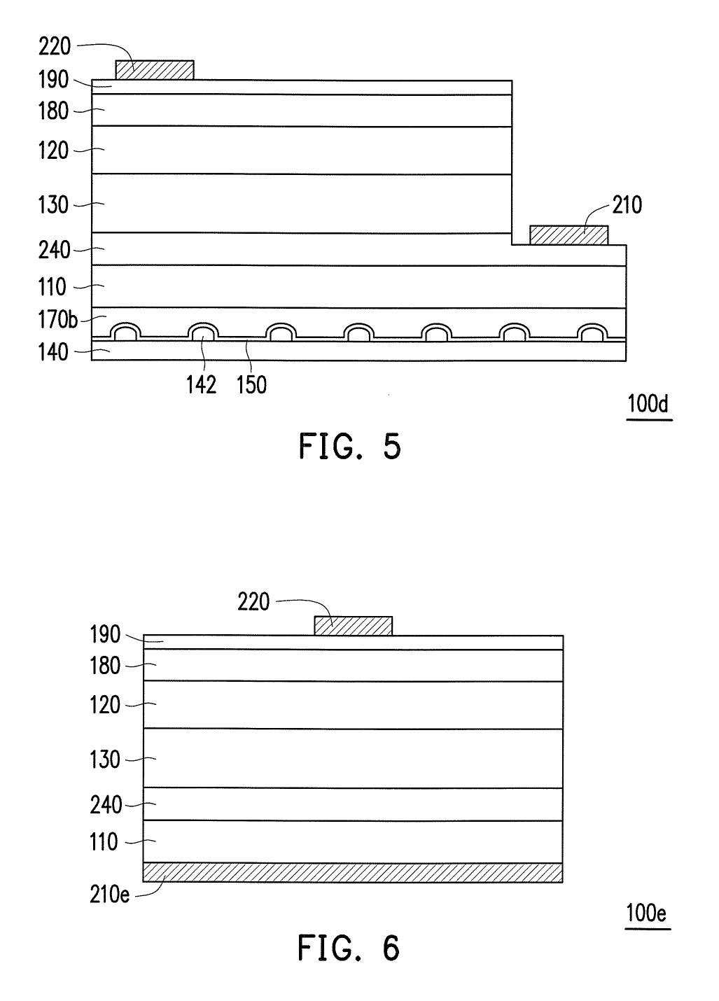

FIG. 5 is a cross-sectional diagram illustrating a semiconductor light-emitting device according to yet another embodiment of the invention. A semiconductor light-emitting device 100d of the present embodiment is similar to the semiconductor light-emitting device 100 of the embodiment illustrated in FIG. 1, but different therefrom in below. In the semiconductor light-emitting device 100d of the present embodiment, the first N-type semiconductor layer 110 directly contacts the second N-type semiconductor layer 170b (which is similar to the second N-type semiconductor layer 170b depicted in FIG. 3, i.e., the second N-type semiconductor layer configured to replace the unintentionally doped semiconductor layer 170 depicted in FIG. 1), and the second N-type semiconductor layer 170b directly contacts the nucleation layer 150.

FIG. 6 is a cross-sectional diagram illustrating a semiconductor light-emitting device according to still another embodiment of the invention. With reference to FIG. 6, a semiconductor light-emitting device 100e of the present embodiment is similar to the semiconductor light-emitting device 100 of the embodiment illustrated in FIG. 1, but different therefrom in below. The semiconductor light-emitting device 100 of FIG. 1 is a horizontal-type LED, in which both the first electrode 210 and the second electrode 220 are located at the same side of the semiconductor light-emitting device 100, while the semiconductor light-emitting device 100e of the present embodiment is a vertical-type LED, in which a first electrode 210e and the second electrode 220 are located at opposite sides of the semiconductor light-emitting device 100. In the present embodiment, the first electrode 210e is an electrode layer disposed on a surface of the first N-type semiconductor layer 110 which faces away from the light-emitting layer 130. However, in other embodiments, a conductive substrate may be disposed between the first electrode 210e and the first N-type semiconductor layer 110. Namely, the first electrode 210e and the first N-type semiconductor layer 110 may be respectively disposed on opposite surfaces of the conductive substrate.

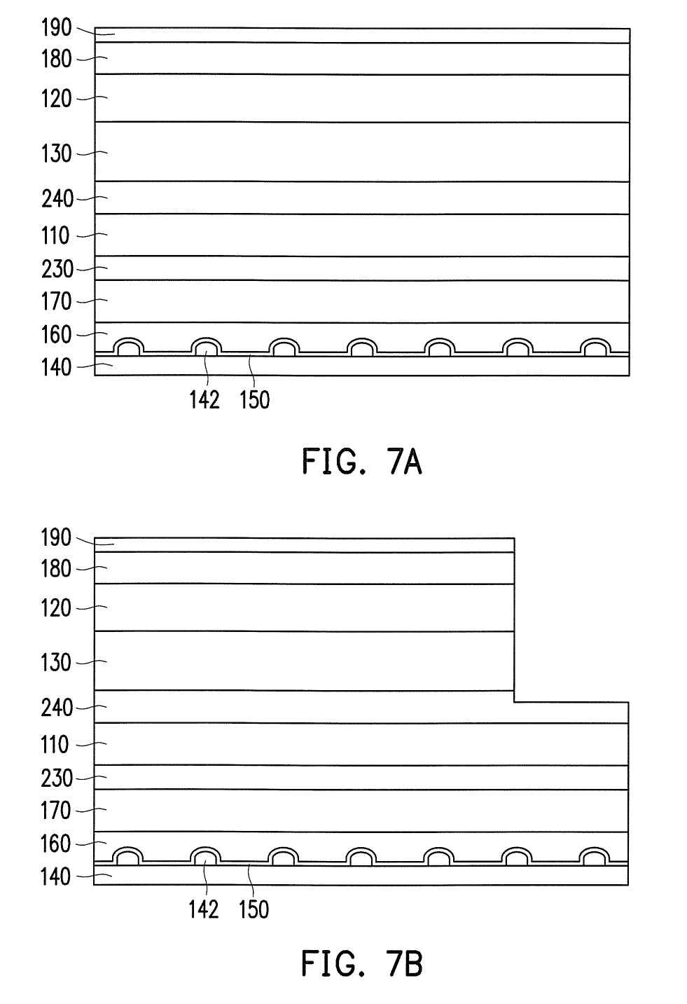

FIG. 7A and FIG. 7B are cross-sectional diagrams illustrating a process of manufacturing method of a semiconductor light-emitting device according to an embodiment of the invention. With reference to FIG. 7A, FIG. 7B and FIG. 1, the manufacturing method of the semiconductor light-emitting device in this embodiment may be utilized to manufacture the semiconductor light-emitting devices (including the semiconductor light-emitting devices 100 and 100a to 100e) of the embodiments above, and hereinafter, the method is utilized to manufacture the semiconductor light-emitting device 100, for example. The manufacturing method of the semiconductor light-emitting device of the present embodiment includes the following steps. First, referring to FIG. 7A, the substrate 140 is provided. Then, the plurality of N-type GaN layers and the plurality of the unintentionally doped AlGaN layers are alternately formed on the substrate 140 to form the first N-type semiconductor layer 110. Thereafter, the light-emitting layer 130 is formed on the first N-type semiconductor layer 110. Afterwards, the P-type semiconductor layer 120 is formed on the light-emitting layer 130.

In the present embodiment, before forming the first N-type semiconductor layer 110, the plurality of GaN layers and the plurality of AlGaN layers may be alternately formed on the substrate 140 to form the unintentionally doped semiconductor layer 170, wherein the first N-type semiconductor layer 110 is formed on the unintentionally doped semiconductor layer 170. In other embodiments, it may also be alternately forming the plurality of N-type GaN layers and the plurality of unintentionally doped AlGaN layers on the substrate 140 to form the second N-type semiconductor layer before forming the first N-type semiconductor layer 110, wherein the first N-type semiconductor layer 110 is formed on the second N-type semiconductor layer.

Specifically, in the present embodiment, the nucleation layer 150, the buffer layer 160, the unintentionally doped semiconductor layer 170, the dislocation termination layer 230, the first N-type semiconductor layer 110, the N-type semiconductor layer 240, the light-emitting layer 130, the P-type semiconductor layer 120, the contact layer 180 and the transparent conductive layer 190 may be formed in sequence on the substrate 140.

Then, in the present embodiment, referring to FIG. 7B, a partial region of each of the layers (which may include the light-emitting layer 130, the P-type semiconductor layer 120, the contact layer 180 and the transparent conductive layer 190) above the N-type semiconductor layer 240 and an upper part of the N-type semiconductor layer 240 on the partial region are etched to form a depression part illustrated in FIG. 7B, so as to expose the N-type semiconductor layer 240 in the partial region. In an another embodiment, the partial region of each layer above the first N-type semiconductor layer 240 and an upper part of the first N-type semiconductor layer 240 on the partial region are etched, so as to expose the first N-type semiconductor layer 240 in the partial region.

Then, referring to FIG. 1, the first electrode 210 and the second electrode 220 are respectively formed on the exposed part of the N-type semiconductor layer 240 (or the first N-type semiconductor layer 240) and the transparent conductive layer 190, such that the manufacturing of the semiconductor light-emitting device 100 is completed.

To summarize, in the semiconductor light-emitting device provided by the embodiments of the invention, since the first N-type semiconductor layer contains aluminum, the band gap of the first N-type semiconductor layer can be increased and have greater difference from the band gap of the light-emitting layer. Thereby, the proportion of the first N-type semiconductor layer absorbing the light emitted from the light-emitting layer can be reduced, so as to enhance light-emitting efficiency of the semiconductor light-emitting device. Moreover, in the semiconductor light-emitting device provided by the embodiments of the invention, since the resistivity of the first N-type semiconductor layer is anisotropic, the electrons can have a greater drift range in the first N-type semiconductor layer to suppress a current crowding effect, so as to enhance light-emitting efficiency and light-emitting uniformity of the semiconductor light-emitting device. In the manufacturing method of the semiconductor light-emitting device provided by the embodiments of the invention, the plurality of N-type GaN layers and the plurality of unintentionally doped AlGaN layers are alternately formed on the substrate to form the first N-type semiconductor layer, and thus, electrons tends to laterally diffuse easily in the first N-type semiconductor layer. In this way, the current crowding effect can be effectively suppressed, so as to enhance the light-emitting efficiency and the light-emitting uniformity of the semiconductor light-emitting device.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor light-emitting device, comprising:
a first N-type semiconductor layer containing aluminum, the concentration of an N-type dopant thereof being greater than or equal to 5×10¹⁸ atoms/cm³;
a P-type semiconductor layer; and
a light-emitting layer, disposed between the first N-type semiconductor layer and the P-type semiconductor layer, wherein light emitted from the light-emitting layer comprises blue light, ultraviolet (UV) light or a combination thereof.

2. The semiconductor light-emitting device according to claim 1, wherein the first N-type semiconductor layer is an N-type aluminum gallium nitride (AlGaN) layer.

3. The semiconductor light-emitting device according to claim 1, wherein the N-type dopant is silicon.

4. The semiconductor light-emitting device according to claim 1, wherein the first N-type semiconductor layer comprises a plurality of N-type gallium nitride (GaN) layers and a plurality of unintentionally doped AlGaN layers which are alternately stacked.

5. The semiconductor light-emitting device according to claim 1, wherein a resistivity of the first N-type semiconductor layer is anisotropic.

6. The semiconductor light-emitting device according to claim 5, wherein the resistivity of the first N-type semiconductor layer in a thickness direction thereof is greater than the resistivity of the first N-type semiconductor layer in a direction perpendicular to the thickness direction.

7. The semiconductor light-emitting device according to claim 1, further comprising:
a substrate;
an unintentionally doped semiconductor layer, disposed on the substrate and located between the first N-type semiconductor layer and the substrate, wherein the unintentionally doped semiconductor layer contains aluminum; and
a dislocation termination layer, disposed between the first N-type semiconductor layer and the unintentionally doped semiconductor layer.

8. The semiconductor light-emitting device according to claim 7, wherein the unintentionally doped semiconductor layer comprises a plurality of GaN layers and a plurality of AlGaN layers which are alternately stacked.

9. The semiconductor light-emitting device according to claim 7, further comprising a buffer layer disposed between the unintentionally doped semiconductor layer and the substrate.

10. The semiconductor light-emitting device according to claim 1, further comprising:
a substrate; and
a second N-type semiconductor layer, disposed on the substrate and located between the first N-type semiconductor layer and the substrate, wherein the second N-type semiconductor layer contains aluminum.

11. The semiconductor light-emitting device according to claim 10, further comprising:
a dislocation termination layer, disposed between the first N-type semiconductor layer and the second N-type semiconductor layer.

12. The semiconductor light-emitting device according to claim 10, further comprising:
a buffer layer, disposed between the second N-type semiconductor layer and the substrate; and
a dislocation termination layer, disposed between the second N-type semiconductor layer and the buffer layer.

13. The semiconductor light-emitting device according to claim 10, wherein concentration of aluminum in the second N-type semiconductor layer is greater than concentration of aluminum in the first N-type semiconductor layer.

14. The semiconductor light-emitting device according to claim 10, wherein the second N-type semiconductor layer comprises a plurality of N-type GaN layers and a plurality of unintentionally doped AlGaN layers which are alternately stacked.

15. The semiconductor light-emitting device according to claim 14, wherein a resistivity of the second N-type semiconductor layer is anisotropic.

16. A semiconductor light-emitting device, comprising:
a first N-type semiconductor layer containing aluminum, a resistivity of the first N-type semiconductor layer being anisotropic;
a P-type semiconductor layer; and
a light-emitting layer, disposed between the first N-type semiconductor layer and the P-type semiconductor layer.

17. The semiconductor light-emitting device according to claim 16, wherein the first N-type semiconductor layer is an N-type AlGaN layer.

18. The semiconductor light-emitting device according to claim 16, further comprising:
a substrate; and
a second N-type semiconductor layer, disposed on the substrate and located between the first N-type semiconductor layer and the substrate, wherein the second N-type semiconductor layer contains aluminum, concentration of aluminum in the second N-type semiconductor layer is greater than concentration of aluminum in the first N-type semiconductor layer, and a resistivity of the second N-type semiconductor layer is anisotropic.

19. A manufacturing method of a semiconductor light-emitting device, comprising:
providing a substrate;
alternately forming a plurality of N-type GaN layers and a plurality of unintentionally doped AlGaN layers on the substrate to form a first N-type semiconductor layer;
forming a light-emitting layer on the first N-type semiconductor layer; and
forming a P-type semiconductor layer on the light-emitting layer.

20. The manufacturing method according to claim 19, further comprising:
before forming the first N-type semiconductor layer, alternately forming a plurality of GaN layers and a plurality of AlGaN layers on the substrate to form an unintentionally doped semiconductor layer, wherein the first N-type semiconductor layer is formed on the unintentionally doped semiconductor layer.

21. The manufacturing method according to claim 19, further comprising:
before forming the first N-type semiconductor layer, alternately forming a plurality of N-type GaN layers and a plurality of unintentionally doped AlGaN layers on the substrate to form a second N-type semiconductor layer, wherein the first N-type semiconductor layer is formed on the second N-type semiconductor layer, and concentration of aluminum in the second N-type semiconductor layer is greater than concentration of aluminum in the first N-type semiconductor layer.

22. The manufacturing method according to claim 19, wherein concentration of an N-type dopant of the first N-type semiconductor layer is greater than or equal to 5×10¹⁸ atoms/cm³.
